(19) United States
(12) Patent Application Publication
(10) Pub. No.: US 2017/0307842 A1
(43) Pub. Date: Oct. 26, 2017

(54) CAMERA MODULE MANUFACTURING METHOD AND CAMERA MODULE MANUFACTURING APPARATUS

(71) Applicant: Sharp Kabushiki Kaisha, Sakai City, Osaka (JP)

(72) Inventors: Masahiro NAKAMURA, Sakai City (JP); Junichi MURAKAMI, Sakai City (JP); Yoshihiro SOHTOME, Sakai City (JP); Satoshi FUJIWARA, Sakai City (JP); Yuhichi EGUCHI, Sakai City (JP)

(21) Appl. No.: 15/518,308

(22) PCT Filed: Sep. 7, 2015
(86) PCT No.: PCT/JP2015/075371

§ 371 Date: Apr. 11, 2017

(30) Foreign Application Priority Data
Oct. 16, 2014 (JP) 2014-212092

(51) Int. Cl. G02B 7/02; H04N 5/225; H01L 27/146

(52) U.S. Cl. CPC G02B 7/025; H01L 27/14685; H04N 5/2254

(57) ABSTRACT

A reduction in resolving power due to the tilt of an imaging element is easily solved. A camera module manufacturing apparatus according to the present embodiment is a camera module manufacturing apparatus for manufacturing a camera module 100 including an optical lens 28, a lens fixing member 29, an actuator block 21 that drives the optical lens 28 to be displaced along an optical axis, and an imaging block on which the actuator block 21 is mounted via an adhesive 25, the imaging block including a substrate 22 and an imaging element 23 packaged on the substrate 22 to capture an image formed by light from the optical lens 28, the camera module manufacturing apparatus including:

a pedestal 27 that directly supports the imaging element 23 horizontally from a side opposite to an imaging surface; and an actuator block mounting head 32 that mounts and fixes the actuator block 21 onto the substrate 22 horizontally in an at least partially floating state so that a central axis 26 of the optical lens 28 is perpendicular to the imaging surface of the imaging element 23 supported by the pedestal 27.

### TECHNICAL FIELD

The present invention relates to a camera module manufacturing method and a camera module manufacturing apparatus.

### BACKGROUND ART

A camera module is an integrated combination of an imaging block, a lens fixing member, and an actuator block. The imaging block includes an imaging element such as a CCD or a CMOS, a substrate on which the imaging element is mounted, and the like. The lens fixing member includes an optical lens that forms an image on the imaging element. The actuator block enables the lens fixing member to be moved. Such a camera module is manufactured, for example, in the following manner.

First, an imaging block and an actuator block are assembled as separate entities through the respective steps. The actuator block includes an optical lens that is movable along an optical axis and a lens tube in which the optical lens is fixed.

Next, after the actuator block and the imaging block have been positioned, they are fixed to each other with an adhesive such as an ultraviolet curable resin. After the actuator block and the imaging block have been fixed to each other, a focus adjustment is made by adjusting the position of the lens tube along the optical axis. Upon completion of the focus adjustment, an optical block and the lens tube are fixed to each other by applying an adhesive such as an ultraviolet curable resin to a space between them.

Camera modules assembled through such steps have their imaging characteristics inspected, and those of them without problems with visual inspection as well are shipped as products.

Meanwhile, in the process of assembling a camera module, there is a problem of resolving power due to an assembly error. The problem of resolving power leads to a reduction in production yield because of a reduction in resolving power when the occurrence of a tilt at the time of fixing of the imaging element disables the imaging element and the central axis of the lens to form an angle of 90 degrees, while an ideal resolving power is attained when the central axis of the lens forms an angle of 90 degrees with respect to a surface of the imaging element.

To address this problem, PTL 1 proposes a method. To solve the problem of the occurrence of an error in verticality between an image sensor and a lens surface due to warpage of a substrate (PCB), PTL 1 describes a technology directed to a camera module manufacturing apparatus with which consistent references for packaging of a lens housing module (which is equivalent to an AF actuator) and the image sensor are set by packaging the image sensor at a tilt in accordance with the tilt of the substrate by die bonding the substrate with a rim tool including substrate supporting means for supporting the substrate from below.

### CITATION LIST

### Patent Literature

PTL 1: Japanese Unexamined Patent Application Publication No. 2014-3601 (published on Jan. 9, 2014)

### SUMMARY OF INVENTION

### Technical Problem

However, in actuality, the warpage of the substrate is not limited to a given direction, and the direction of tilt often greatly varies according to position within the substrate, although the manufacturing apparatus described in PTL 1 involves the proposal of the method for packaging the lens housing module and the image sensor after having matched their tilts in accordance with the flatness or warpage of the substrate. Therefore, the use of the substrate as a reference for tilts is poor in reproducibility, and the tilt of the image sensor packaged by the rim tool and the tilt of the lens housing module packaged in a separate step after the packaging of the image sensor vary and do not match.

Further, in such a case as that described in PTL 1 where the image sensor and the lens housing are placed on one surface of the substrate, the substrate supporting means can be used, but in a case where the lens housing is mounted on one surface of the substrate and the image sensor is mounted on the other surface of the substrate, the substrate supporting means cannot be used.

Furthermore, in a case where the substrate is made of ceramic, it warps more greatly than in a case where it is made of resin, and in a case where the substrate has an opening in its center, it warps more remarkably.

The present invention has been made to solve the foregoing problems, and it is an object of the present invention to provide a camera module manufacturing method and a camera module manufacturing apparatus that make it possible to easily solve a reduction in resolving power due to the tilt of an imaging element.

### Solution to Problem

In order to solve the foregoing problems, a camera module manufacturing apparatus according to an aspect of the present invention is a camera module manufacturing apparatus for manufacturing a camera module including an optical lens, a fixing member accommodating and holding the optical lens, an actuator that enables the fixing member to be moved and drives the optical lens to be displaced along an optical axis, and an imaging block on which the actuator is mounted via an adhesive, the imaging block including a substrate and an imaging element packaged on the substrate to capture an image formed by light from the optical lens, the camera module manufacturing apparatus including: a supporting section that directly supports the imaging element horizontally from a side opposite to an imaging surface, the supporting section supporting only the imaging element; and a mounting section that mounts and fixes the actuator onto the substrate horizontally in an at least partially floating state so that a central axis of the optical lens is perpendicular to the imaging surface of the imaging element supported by the supporting section.

### Advantageous Effects of Invention

An aspect of the present invention brings about an effect of making it possible to easily solve a reduction in resolving power due to the tilt of an imaging element.

### BRIEF DESCRIPTION OF DRAWINGS

FIG. 1 illustrates diagrams (a), (b), and (d) showing an example of a camera module manufacturing method according to Embodiment 1 and a top view (c) showing the example of the camera module manufacturing method according to Embodiment 1.

FIG. 2 is a diagram showing a method for bonding and fixing an actuator block and an imaging block of a camera module according to Embodiment 1.

FIG. 3 illustrates diagrams (a) to (c) showing a method for holding the actuator block of the camera module according to Embodiment 1.

FIG. 4 is a diagram showing the method for holding the actuator block of the camera module according to Embodiment 1.

FIG. 5 is a diagram showing the method for holding the actuator block of the camera module according to Embodiment 1.

FIG. 6 illustrates a diagram (a) showing an example of a camera module manufacturing method according to Embodiment 2 and (b) a top view showing the example of the camera module manufacturing method according to Embodiment 2.

FIG. 7 is a diagram showing a configuration of a camera module in detail.

FIG. 8 is a cross-sectional view showing a process for manufacturing a camera module and, in particular, a step of preparing a height positioning jip.

FIG. 9 is a cross-sectional view showing the process for manufacturing a camera module and, in particular, a state in which a lens driving device is loaded on the height positioning jip.

FIG. 10 is a cross-sectional view showing the process for manufacturing a camera module and, in particular, a state in which an optical section is fixed in position within a lens holder with the lens driving device loaded on the height positioning jip.

FIG. 11 is a cross-sectional view showing the process for manufacturing a camera module and, in particular, a state in which the height positioning jig has been detached from the lens driving device.

FIG. 12 is a cross-sectional view showing the process for manufacturing a camera module and, in particular, a step of chucking a top surface side of the lens driving device with a mounting device and preparing an imaging section.

FIG. 13 illustrates diagrams (a) to (c) showing examples of camera modules of conventional technologies.

### DESCRIPTION OF EMBODIMENTS

### Conventional Technologies

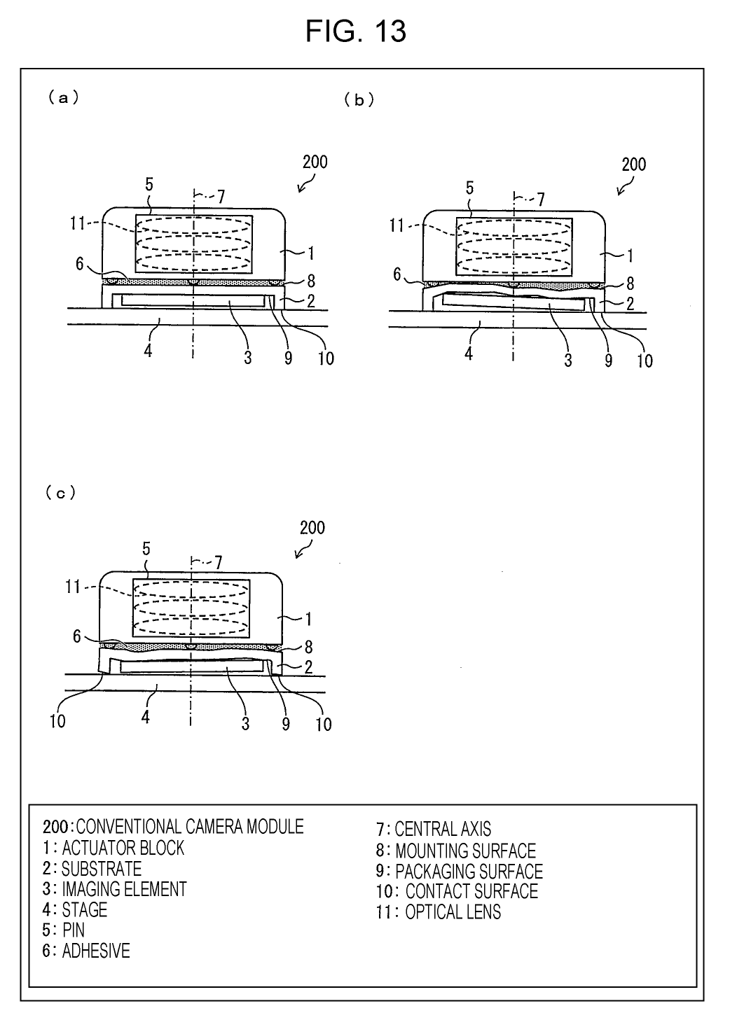

FIG. 13 illustrates diagrams (a) to (c) showing examples of camera modules of conventional technologies. In (a) of FIG. 13, an actuator block 1 that enables a lens fixing member 5 including an optical lens 11 to be moved is coupled via an adhesive 6 or the like to an imaging block including a substrate 2 and an imaging element 3 packaged on the substrate 2. At this time, an ideal resolving power is attained when the imaging element 3 and a central axis 7 of the optical lens 11 form an angle of 90 degrees.

Further, in (a) of FIG. 13, a stage 4 that is used in an actuator block mounting step is ideally installed at an angle of 90 degree with the central axis 7 and, if the imaging element 3 is assembled as designed, is positioned parallel to the imaging element 3.

However, as shown in (b) of FIG. 13, in actuality, the substrate 2, on which the imaging element 3 is packaged, has warpage, and especially in the case of a substrate made of ceramic, it is difficult to suppress warpage. The warpage of the substrate 2 causes the imaging element 3 to be packaged at a tilt with respect to the central axis 7 of the optical lens 11. Further, a mounting surface 8 of the substrate 2 on which the actuator block 1 is mounted is affected by the warpage, with the result that the actuator block 1 per se is mounted at a tilt on the substrate 2 to have a combination of tilts with respect to the imaging element 3.

(c) of FIG. 13 is a diagram showing an example of another conventional technology. As shown in (c) of FIG. 13, the warpage of the substrate 2 further affects a packaging surface 9 on which the imaging element 3 is packaged, the mounting surface 8 on which the actuator block 1 is mounted, and, furthermore, a contact surface 10 that makes contact with the stage 4. These three factors are responsible for tilts associated with the warpage of the substrate 2, and these tilts make it very difficult for the central axis 7 and the imaging element 3 to form an angle of 90 degrees.

The present invention provides a camera module manufacturing method and a camera module manufacturing apparatus that make it possible to obviate the inconveniences arising from the factors responsible for tilts associated with the warpage of the substrate 2. The following describes embodiments of the present invention in detail.

### Embodiment 1

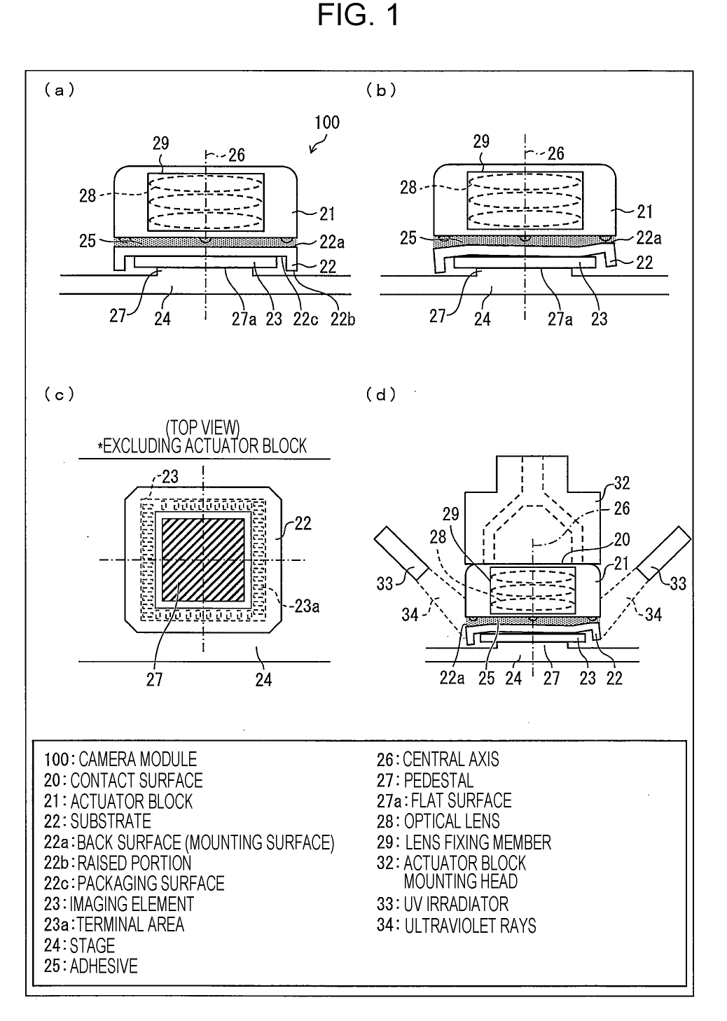

FIG. 1 illustrates schematic views (a) to (d) showing an example of a camera module manufacturing method according to Embodiment 1. As shown in (a) to (d) of FIG. 1, a camera module 100 includes an actuator block 21 and an imaging block. The actuator block 21 enables a lens fixing member 29 accommodating an optical lens 28 to be moved and drives the optical lens 28 to be displaced along an optical axis. The imaging block includes a substrate 22 and an imaging element 23 packaged on the substrate 22. The actuator block 21 is coupled via an adhesive 25 to the imaging block on a stage 24.

Specifically, the imaging block is configured such that the imaging element 23 is packaged with its imaging surface facing a packaging surface 22c of the substrate 22. More specifically, as shown in (c) of FIG. 1, which is a top view of a state excluding the actuator block 21, the imaging element 23 is packaged by flip-chip bonding between a terminal area 23a of the imaging element 23 and the substrate 22. Further, the substrate 22 includes a raised portion 22b raised toward the packaging surface 22c for the entire perimeter of the substrate 22 and a back surface (mounting surface) 22a on which the actuator block 21 is provided. The back surface 22a is opposite to the packaging surface 22c. The actuator block 21 is provided after the application of the adhesive 25 or the like to the back surface 22a of the substrate 22. Further, the raised portion 22b surrounds the imaging element 23 and is designed to be longer than the thickness of the imaging element 23.

Further, as shown in (a) of FIG. 1, the stage 24, which is used in the actuator block mounting step, includes a pedestal 27 of a predetermined height and holds the imaging block by receiving a back surface of the imaging element 23 (opposite to the imaging surface) with a flat surface 27a of the pedestal 27. Further, the pedestal 27 is set at such a height that the raised portion 22b does not make contact with the stage 24 when the imaging block is placed on the pedestal 27. Thus, even in the presence of the warpage of the substrate 22 as shown in (b) of FIG. 1, unlike in the absence of the warpage of the substrate 22 as shown in (a) of FIG. 1, the imaging element 23 can be kept parallel to the stage 24; therefore, the imaging element 23 is not affected by the warpage of the substrate 22 even in a case where the imaging element 23 is packaged at a tilt with respect to the substrate 22.

Further, when the actuator block 21 and the imaging block are fixed to each other by the adhesive 25 or the like, an adjustment is made so that a central axis 26 of the optical lens 28 of the actuator block 21 forms an angle of approximately 90 degrees (with a margin of error of approximately ±5 degrees) with respect to the imaging element 23 with the actuator block 21 either out of contact with or in partial contact with (i.e. at least partially floating above) the back surface 22a of the substrate 22.

More specifically, as shown in (d) of FIG. 1, the actuator block 21 is held by an actuator block mounting head 32, and a contact surface 20 between the actuator block mounting head 32 and the actuator block 21 is adjusted to be parallel to the flat surface 27a of the pedestal 27 on which the imaging element 23 is held. Further, the actuator block 21 and the imaging block are fixed to each other by the adhesive 25 or the like with the actuator block 21 floating above the back surface 22a of the substrate 22 so as not to be affected by the warpage of the substrate 22.

Note here that, in (d) of FIG. 1, the adhesive 25, via which the actuator block 21 and the imaging block are coupled to each other, is an ultraviolet curable resin that fixes the actuator block 21 and the imaging block to each other by being cured upon irradiation with ultraviolet rays 34 from a UV irradiator 33. It should be noted that the adhesive 25 may alternatively be a thermosetting resin that may fix the actuator block 21 and the imaging block to each other by being cured by a spot heater or the like.

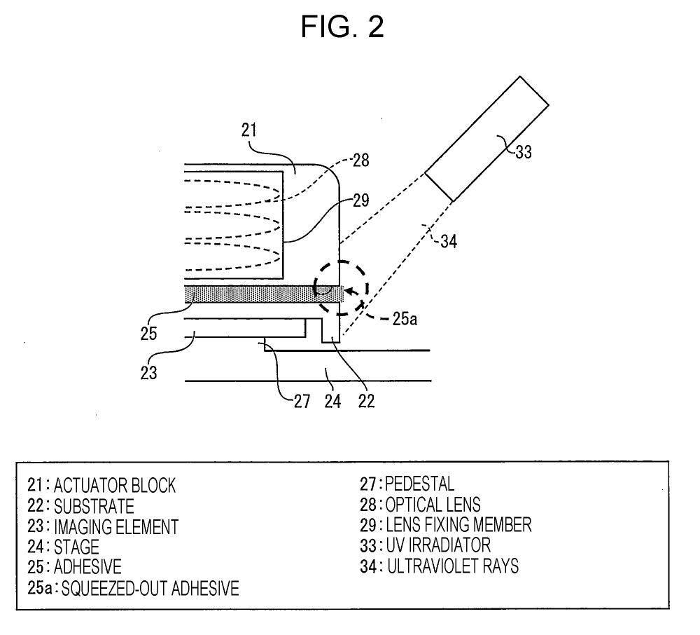

Further, as shown in FIG. 2, the adhesive 25 is applied in such an adjusted amount as to be in a state 25a where the adhesive 25 is squeezed out from between the actuator block 21 and the substrate 22. This makes it easy to, in fixing the actuator block 21 and the imaging block to each other with the ultraviolet curable resin, the thermosetting resin, or the like, expose the resin to the ultraviolet rays radiated from the UV irradiator or to hot air blown out from the spot heater.

It should be noted that, the squeezed-out adhesive 25a, when cured, has an adhesive strength with which the actuator block 21 and the imaging block are temporarily fixed to each other to such a degree as not to suffer from misalignment, tilting, or the like, and after this step, the actuator block 21 and the imaging block are permanently fixed to each other, for example, by heat curing in a thermostatic oven or by increased irradiation with ultraviolet rays.

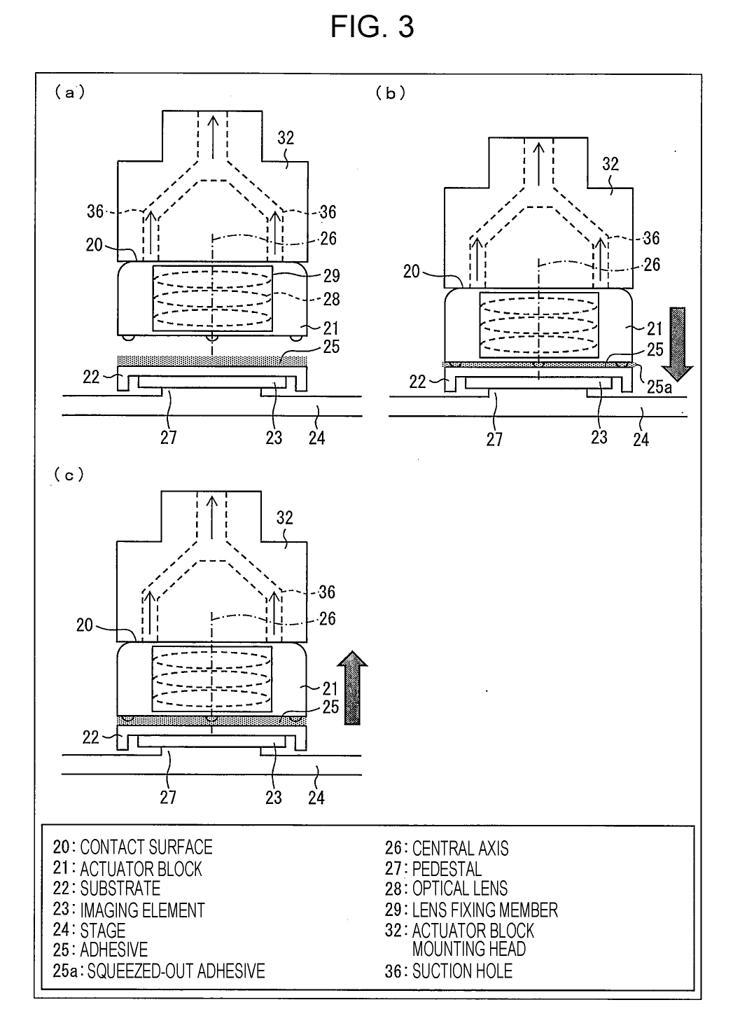

A step of mounting the actuator block mounting head 32 is described here. FIG. 3 illustrates diagrams (a) to (c) showing the flow of the step of mounting the actuator block mounting head 32. In (a) of FIG. 3, the actuator block mounting head 32 has a suction hole 36 formed inside thereof. The suction hole 36 connects upper-surface and lower-surface suction ports to each other. The actuator block mounting head 32 holds the actuator block 21 by sucking the contact surface 20 under air suction through the suction ports.

As shown in (b) of FIG. 3, in mounting the actuator block 21, the actuator block mounting head 32 holding the actuator block 21 performs an operation of pressing the actuator block 21 against the substrate 22 in such a manner as to compress the adhesive 25. After that, as shown in (c) of FIG. 3, the actuator block mounting head 32 holding the actuator block 21 performs an operation of causing the actuator block 21 to float at a predetermined height. This makes it possible to always keep the actuator block 21 at the same height with reference to the back surface 22a of the substrate 22 and surely connect the actuator block 21 and the imaging block to each other via the adhesive 25.

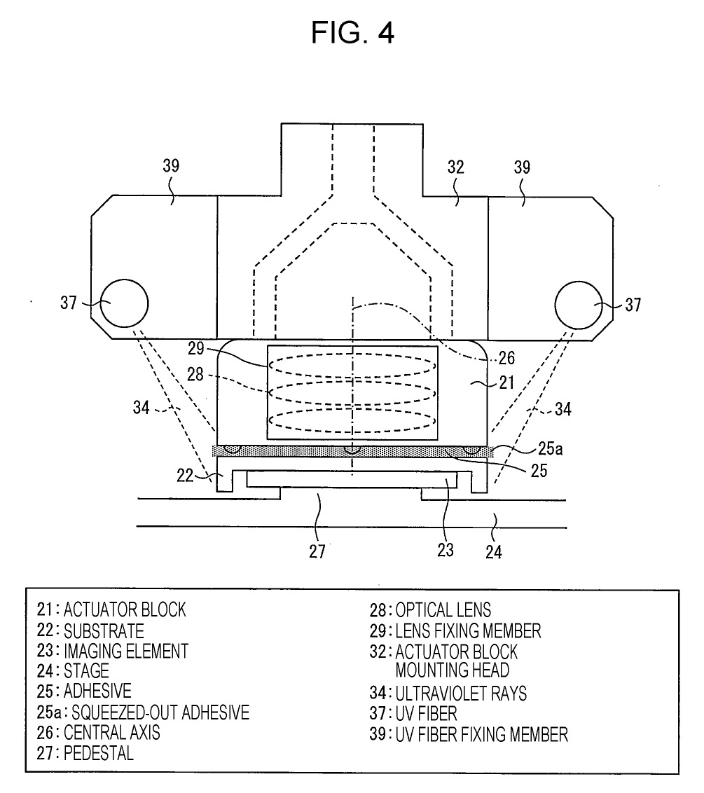

It should be noted that although, as shown in (d) of FIG. 1, the present embodiment has mentioned curing the adhesive with the UV irradiator, the spot heater, or the like, the actuator block mounting head 32 may be structured as shown in FIG. 4 such that a UV fiber fixing member 39 is attached to both right and left sides of the actuator block mounting head 32 and a UV fiber 37 is integrated with the actuator block mounting head 32. Instead of the UV fiber 37, a spot heater may be mounted in this structure.

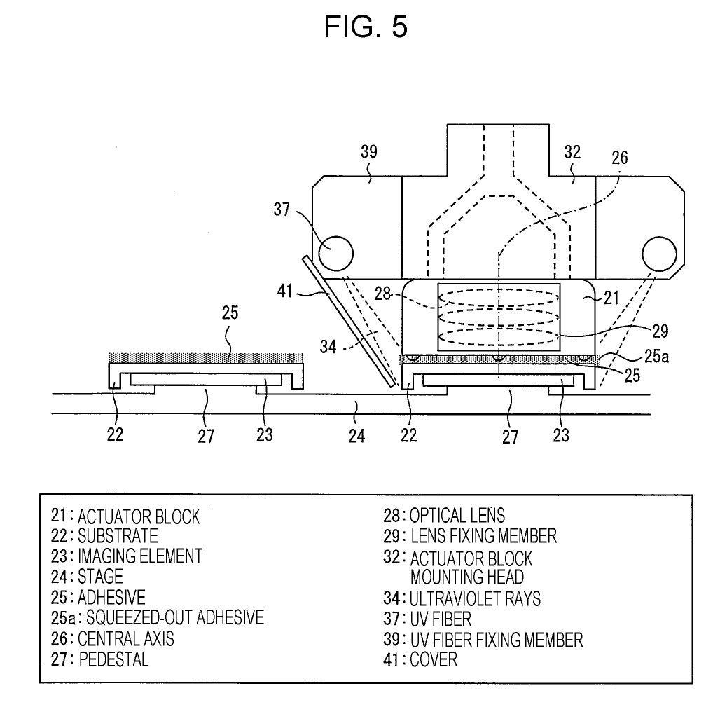

Further, the actuator block mounting head 32 may be structured such that a cover 41 is attached to the actuator block mounting head 32. Alternatively, as shown in FIG. 5, the cover 41 may be attached to the UV fiber fixing member 39. The cover 41 extends from a side of the UV fiber 37 to the squeezed-out adhesive 25a along the direction of radiation. In this way, the cover 41 prevents an ultraviolet curable resin (adhesive) 25 applied to another imaging block placed in the immediate vicinity from being irradiated with the ultraviolet rays 34 radiated from the UV fiber 37 attached to the actuator block mounting head 32. This makes it possible to obviate the inconveniences arising from curing an ultraviolet curable resin (adhesive) 25 applied to another imaging block. Further, the cover 41 always moves together with the actuator block mounting head 32 and can therefore surely achieve covering while saving space within the apparatus. It should be noted that although the cover 41 is here configured to be attached to the UV fiber fixing member 39, the cover 41 may be replaced by another member that prevents diffusion of the ultraviolet rays 34 out of the irradiated region. The same applies to a case where the spot heater or the like is used.

### Embodiment 2

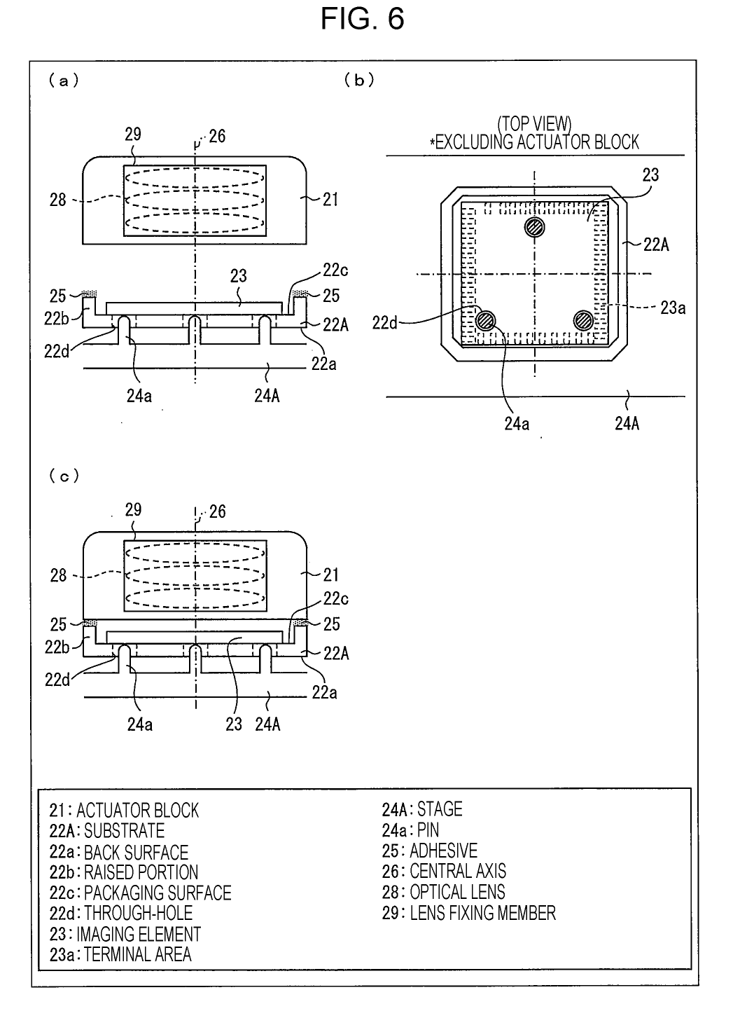

FIG. 6 illustrates diagrams (a) and (b) showing an example of a camera module manufacturing method according to Embodiment 2. A camera module 100A of Embodiment 2 differs from the camera module 100 of Embodiment 1 in that the camera module 100A of Embodiment 2 includes a substrate 22A in place of the substrate 22 and includes a stage 24A in place of the stage 24. The other components of the camera module 100A of Embodiment 2 are identical to those of the camera module 100 of Embodiment 1 and, as such, are not repeatedly described here.

As shown in (a) and (b) of FIG. 6, the imaging block includes the substrate 22A and the imaging element 23 packaged on the substrate 22A. Specifically, the imaging element 23 is packaged on the substrate 22A such that a surface of the imaging element 23 opposite to the imaging surface faces the back surface 22a. It should be noted that, as in the case of Embodiment 1, the imaging element 23 is packaged by flip-chip bonding between the terminal area 23a of the imaging element 23 and the substrate 22A.

The substrate 22A of Embodiment 2 differs from the substrate 22A of Embodiment 1 in that the substrate 22A of Embodiment 2 has three through-holes 22d provided therein, and the stage 24A of Embodiment 2 differs from the stage 24 of Embodiment 1 in that the stage 24A of Embodiment 2 has three pins 24a provided in place of the pedestal 27 of the stage 24 of Embodiment 1. The imaging block is placed so that the pins 24a are fitted in the through-holes 22d such that the back surface 22a of the substrate 22A opposite to the mounting surface 22c faces the stage 24A (i.e. such that the raised portion 22b faces the actuator block 21), whereby the imaging element 23 is supported by the three pins 24a from below. This achieves a structure that holds the imaging element 23 in a horizontal position. The actuator block 21 is fixed to the imaging block by applying the adhesive 25 to a top end face of the raised portion 22b of the substrate 22A. It should be noted that, in this case, too, as shown in (c) of FIG. 6, the actuator block 21 and the imaging block are fixed to each other via the adhesive 25 or the like with the actuator block 21 floating above the top end surface of the raised portion 22b so as not to be affected by the warpage of the substrate 22A (i.e. irregularities in the height of the raised portion 22b).

It should be noted that it is possible to substitute the pins 24a for the pedestal 27 of the stage 24 of Embodiment 1. In this case, the three pins 24a are arranged on the stage 24 in such a manner as to stably support the imaging element 23.

### Embodiment 3

In Embodiments 1 and 2, the actuator block mounting head 32 is used to place the actuator block 21 on the imaging block parallel to the flat surface 27a of the pedestal 27. However, in order for the central axis 26 of the optical lens 28 to be perpendicular to the imaging surface of the imaging element 23, it is preferable that the optical lens 28 be accommodated so that the contact surface 20 of the actuator block 21 that makes contact with the actuator block mounting head 32 is perpendicular to the central axis 26 of the optical lens 28. The following details an actuator block 21 configured to achieve such a configuration.

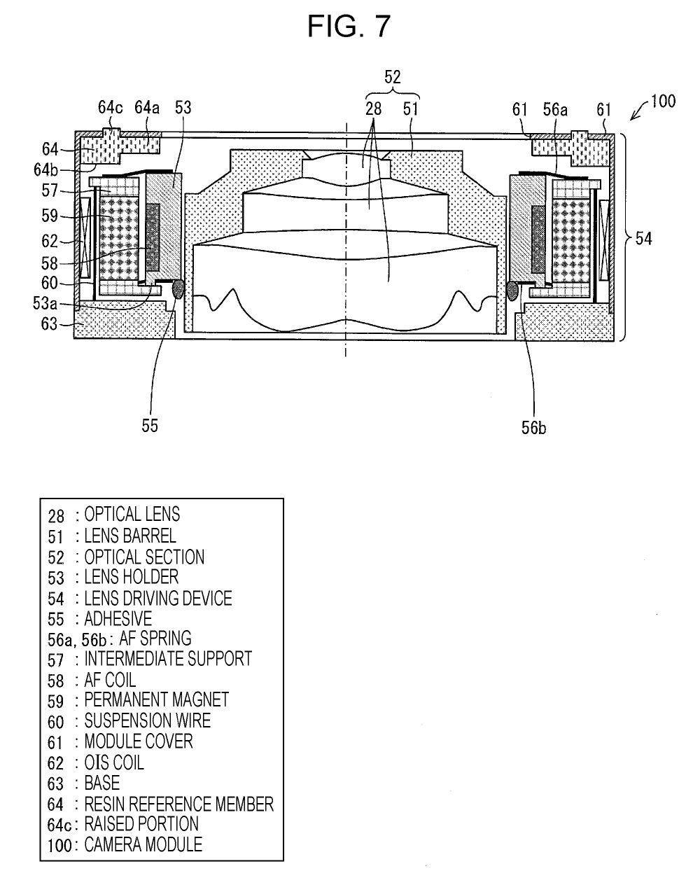

FIG. 7 is a diagram showing a configuration of an actuator block in detail. As shown in FIG. 7, an optical section 52 of the camera module 100 includes one or more optical lenses 28 and a lens barrel 51 that supports the optical lenses 28. The optical section 52 is surrounded by a lens driving device 54. The lens driving device 54 includes a lens holder 53. Note here that the lens driving device 54 corresponds to the actuator block 21 and the lens holder 53 corresponds to the lens fixing member 29. The lens holder 53 holds the lens barrel 51 bonded and fixed to the inner part of the lens holder 53 by an adhesive 55. Before being fixed by the adhesive 55, the lens barrel 51 (or the optical section 52) is slidable along an optical axis with respect to the lens holder 53. That is, the outer surface of the lens barrel 51 and the inner surface of the lens holder 53 constitute not a screw structure but a fit structure (clearance fit).

The lens driving device 54 includes the lens holder 53, an intermediate support 57, and a fixed section. The fixed section includes a module cover 61 (metal cover), an OIS (optical image stabilizer) coil 62, a base 63, and the like. The lens holder 53 to which the optical section 52 is fixed by the adhesive 55 is supported by two upper and lower AF (autofocus) springs 56a and 56b on the intermediate support 57 in such a manner as to be movable along the optical axis. An AF coil 58 is fixed in the outer periphery of the lens holder 53. Further, the lens holder 53 has a raised portion 53a formed in the lower part thereof, and the raised portion 53a is in contact with the intermediate support 57 at a mechanical end of a focal point at infinity in the range of movement along the optical axis (i.e. a reference position in the range of movement on the side of the imaging element).

A permanent magnet for AF driving and a permanent magnet for image stabilization are fixed in the intermediate support 57. In the present embodiment, a permanent magnet 59 serving as both of these two types of magnet is fixed in the intermediate support 57. The intermediate support 57 is supported by four suspension wires 60 (only two of which are illustrated) on the fixed section (which is the base 63 here) in such a manner as to be movable along two axes perpendicular to the optical axis. This causes the intermediate support 57, the permanent magnet 59, the AF springs 56a and 56b, the lens holder 53, the AF coil 58, the lens barrel 51, and the optical lenses 28 to be integrally driven in a direction perpendicular to the optical axis.

Note here that the lens barrel 51 and an opening 63a of the base 63 be placed at a clearance from each other that takes on an appropriate value. A reason for this is that in a case where a drop impact or the like causes lateral displacement of the lens holder 53, the lateral displacement of the lens holder 53 may cause the lens barrel 51 to hit the base 63 and thus receive an impact that causes the lens barrel 51 to be damaged or causes the optical lenses 28 to slip out of the lens barrel 51. Accordingly, in the present embodiment, the size of the clearance between the lens barrel 51 and the opening 63a of the base 63 is set so that the lens barrel 51 does not come into direct contact with the base 63 even in the case of maximum lateral displacement of the lens holder 53.

The module cover 61 is fixed to the base 63 and placed to cover the side and upper surfaces of the intermediate support 57. The OIS coil 62 is fixed to the side surface of the inner side of the module cover 61.

A resin reference member 64 is fixed to an inner top surface side of the module cover 61. The resin reference member 64 includes a portion 64a (second portion) that serves as a stopper for the lens holder 53, a portion 64b (second portion) that serves as a stopper for the intermediate support 57, and a raised portion (first portion) 64c. The portion 64a, which serves as a stopper, limits the range of movement within which the lens holder 53 is driven along the optical axis for an autofocus function. The portion 64b, which serves as a stopper, limits the range within which the intermediate support 57, which serves as a movable part for an image stabilization function, can move in a direction along the optical axis in which the intermediate support 57 is not supposed to be driven. The portions 64a and 64b, which serve as stoppers, of the resin reference member 64 are placed inside of the module cover 61. The raised portion 64c is more raised toward the top surface side than the module cover 61 through holes provided in the top surface side of the module cover 61. That is, in the lens driving device 54, the raised portion 64c of the resin reference member 64 is most raised toward the top surface side. The raised portion 64c is more raised toward the top surface side than any other portion of the resin reference member 64 and exposed from the module cover 61. In the lens driving device 54, at least three of these raised portions 64c are provided. This is because the raised portions 64c form a reference surface and the reference surface is defined with three of these raised portions 64c. It should be noted that, for example, four or more of these raised portions 64c that define the reference surface may be provided. It is preferable that the reference surface defined by the plurality of raised portions 64c have a flatness of 20 μm or less, more preferably 10 μm or less.

Although the raised portions 64c of the resin reference member 64 have been described here as being more raised toward the top surface side than the module cover 61, this does not imply any limitation. For example, the height of each of the raised portions 64c from the inner surface of the module cover 61 may be approximately half of the thickness of the module cover 61. In this case, the after-mentioned height positioning jig 71 is provided with a plurality of raised portions that correspond to the raised portions 64c. Inserting the raised portions of the height positioning jig 71 into the holes of the module cover 61 allows the raised portions of the height positioning jig 71 and the raised portions 64c of the resin reference member 64 to come into contact with each other.

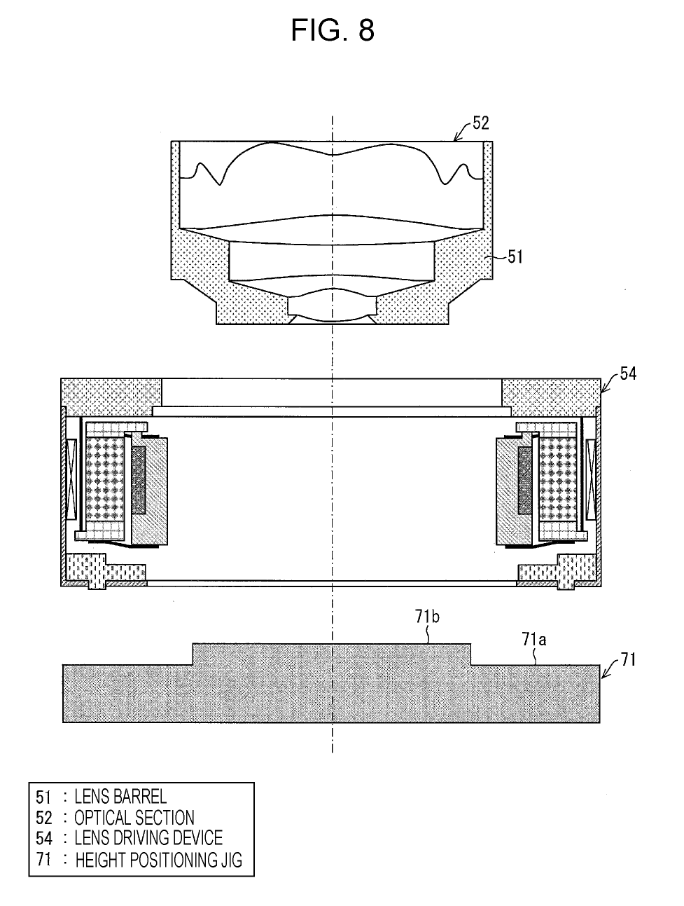

The following describes a process for manufacturing an actuator block 21. FIG. 8 is a diagram showing a process for manufacturing an actuator block. As shown in FIG. 8, the height positioning jig 71 is prepared separately from the optical section 52 and the lens driving device 54, which have been separately assembled.

First, the process starts with the lens driving device 54 and the optical section 52 placed upside down. That is, in the present embodiment, the lens driving device 54 has its top surface side (subject's side) loaded on the height positioning jig 71. The height positioning jig 71 has a flat surface 71a and a raised portion 71b raised from the flat surface 71a. The lens driving device 54 is loaded on the flat surface 71a so that the plurality of raised portions 64c of the resin reference member 64 make contact with the flat surface 71a. The lens barrel 51 of the optical section 52 is loaded on the raised portion 71b. The difference in height between the raised portion 71b and the flat surface 71a defines the height positions of the lens driving device 54 and the optical section 52.

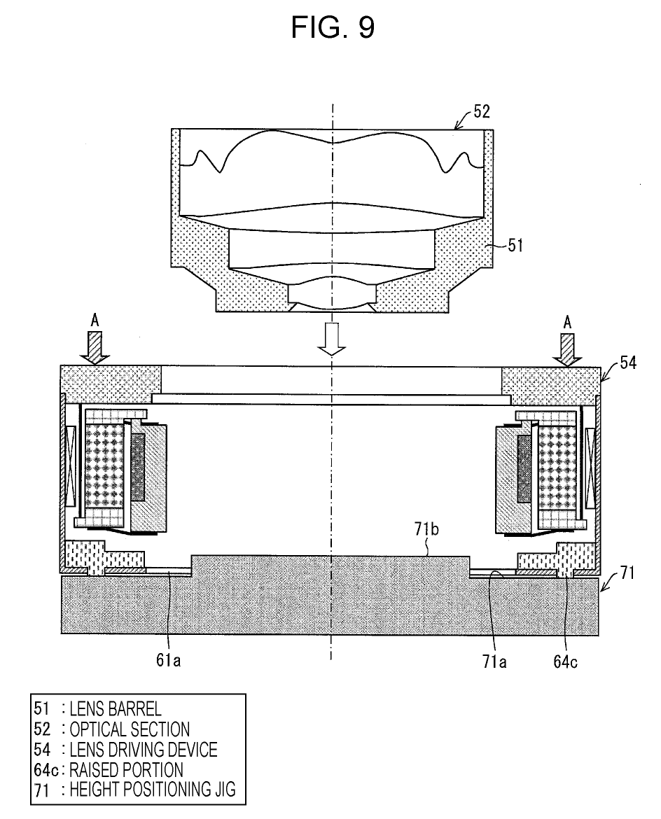

The following describes, with reference to FIG. 9, a state in which the lens driving device 54 is mounted on the height positioning jig 71.

The lens driving device 54 is mounted on the flat surface 71a of the height positioning jig 71 as mentioned above, with the result that the raised portion 71b is fitted in the top surface side of the lens driving device 54 and the inner side of the opening 61a of the module cover 61.

Note here that it is desirable that while the lens driving deice 54 is mounted on the flat surface 71a of the height positioning jig 71, a pressing force be applied to the lens driving device 54 in a direction indicated by hatched arrows A in FIG. 9. A reason for this is to prevent the lens driving device 54 from floating (moving away) from the height positioning jig 71, as it is necessary, as mentioned above, to highly accurately position the lens barrel 51 with respect to the top surface of the lens driving device 54. The plurality of raised portions 64c (subject's side reference surface) of the lens driving device 54 come into contact with the flat surface 71a (first reference surface) of the height positioning jig 71.

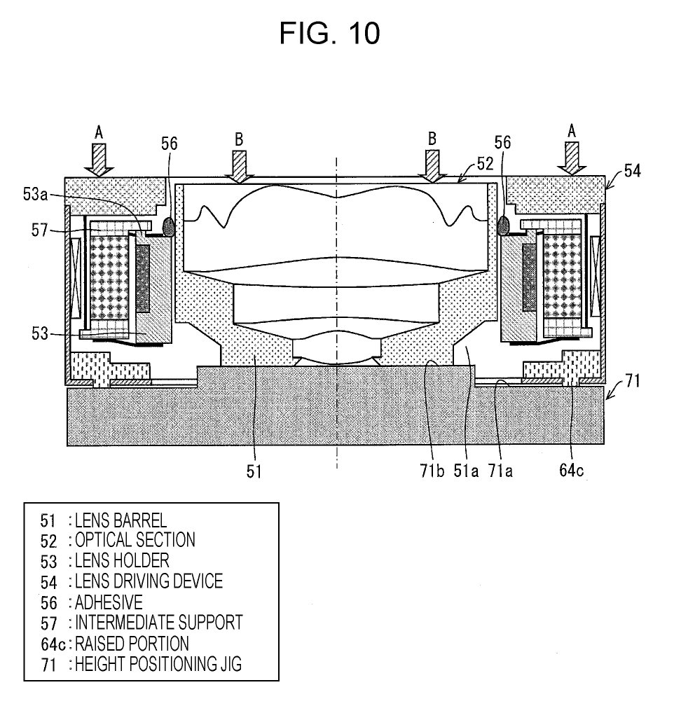

The following describes, with reference to FIG. 10, a state in which the lens barrel 51 (optical section 52) is mounted in the lens driving device 54 so that the lens barrel 51 comes into contact with the raised portion 71b of the height positioning jig 71. In the present embodiment, the lens barrel 51 has its top surface side loaded on the height positioning jig 71.

The optical section 52 is slid into the lens holder 53 of the lens driving device 54. In order for the lens barrel 51 to have its upper end face (subject's side surface) in contact with the raised portion 71b (second reference surface) of the height positioning jig 71, it is desirable that a pressing force be applied in a direction indicated by hatched arrows B in FIG. 10. It should be noted that it is desirable that the pressing force applied to the lens driving device 54 as indicated by the hatched arrows A in FIG. 9 be continuously applied. This is because an error occurs in the presence of floating, as both the lens driving device 54 and the optical section 52 have their reference positions set by mechanical contact between members. In such a state of application of the pressing forces (in the position where the lens barrel 51 comes into contact with the raised portion 71b), the lens holder 51 is bonded and fixed to the lens holder 53 by the adhesive 56. At this time, the raised portion 53a of the lens holder 53 is in contact with the intermediate support 57.

Note here that although, in FIG. 10, the adhesive 55 is applied to a boundary portion of the bottom surface side (which faces upward in FIG. 10) of the lens holder 53 with the lens barrel 51, this does not imply any limitation. It is alternatively possible to inject an adhesive into the space between the lens barrel 51 and the lens holder 53 in advance and cure the adhesive after positioning. It is desirable that the adhesive used here be a UV curable adhesive, a thermosetting adhesive, or a UV curable and thermosetting adhesive. In a case where it is difficult to put the whole of such an assembling apparatus into a furnace for thermal curing, it is possible to use a UV curable and thermosetting adhesive, cure the adhesive with UV in the assembling apparatus, and then cure the adhesive with heat with the lens driving device 54 detached from the assembling apparatus and placed on the height positioning jig 71 or with the lens driving device 54 detached from the height positioning jig 71 as well and put into the furnace. In a case where it is impossible to inject a sufficient amount of adhesive from the bottom surface side of the lens driving device 54, a new supply of adhesive may be put into a recess 51a of the lens barrel 51 from the top surface side after temporary fixing has been done by curing the adhesive on the bottom surface side.

In the state shown in FIG. 10, the lens barrel 51 is inserted in the lens holder 53 with the lens holder 53 in contact with the intermediate support 57. There is a slight clearance between the lens barrel 51 and the lens holder 53, and the lens barrel 51 is attached not in accordance with the precision of a hole of the lens holder 53 but with a degree of accuracy according to the raised portion 71b of the height positioning jig 71. That is, the lens barrel 51 is fixed to the lens holder 53 with reference to the flat surface (top surface side flat surface) defined by the plurality of raised portions 64c of the resin reference member 64. For this reason, the tilt of the lens barrel 51 is not affected by the tilt of the lens holder 53, with the result that the lens barrel 51 is fixed with reference to the top surface of the lens driving device 54. The foregoing step constitutes a lens combining step.

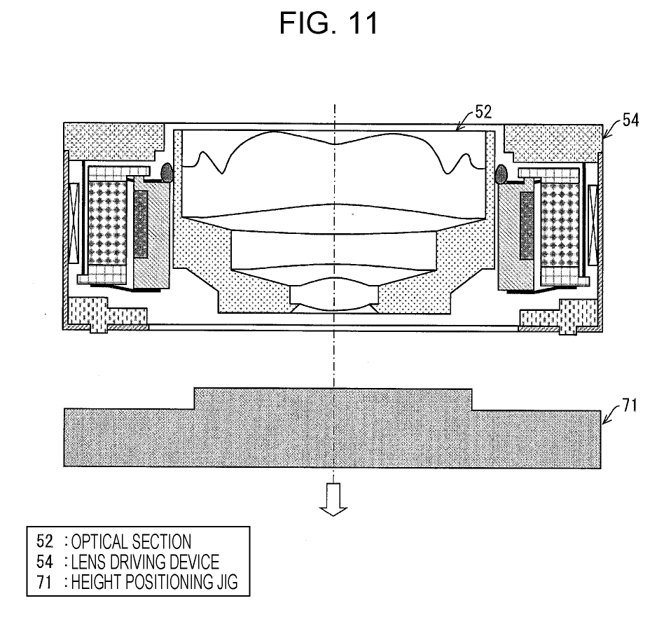

The following describes, with reference to FIG. 11, a state in which the height positioning jig 71 has been detached from the lens driving device 54.

As shown in FIG. 11, upon completion of fixing of the optical section 52 to the lens driving device 54, the height positioning jig 71 is detached from the lens driving device 54. The height positioning jig 71 is a jig for effecting positioning of the optical section 52 with respect to the lens driving device 54 and, as such, is no longer needed after the lens barrel 51 has been bonded and fixed to the lens holder 53.

The following describes a method that is different from the aforementioned method for holding the actuator block 21 with the actuator block mounting head 32 and, in particular, a step of chucking the lens driving device 54 with a mounting device 72.

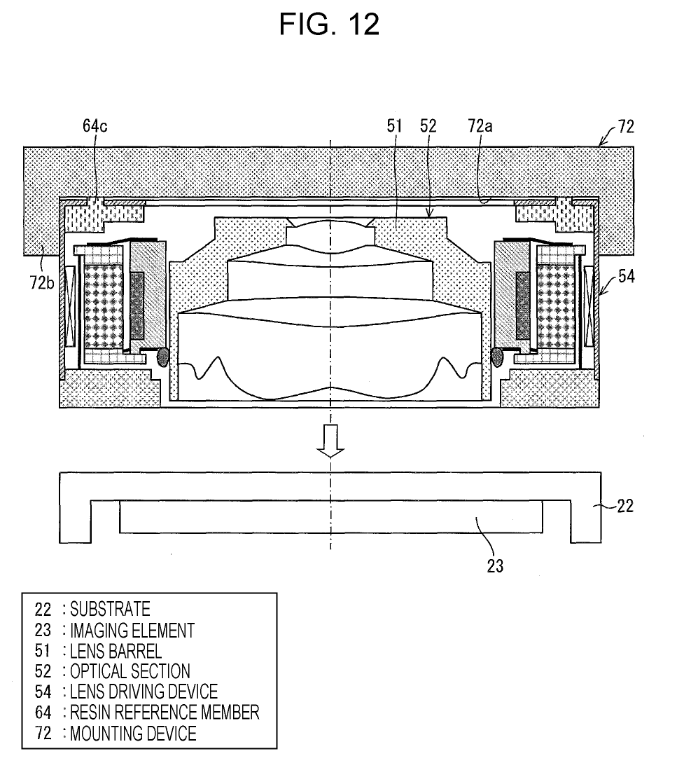

As shown in FIG. 12 (which omits to illustrate the adhesive 25), the lens driving device 54 to which the optical section 52 is attached is chucked (temporarily fixed) by the mounting device 72. During chucking, the plurality of raised portions 64c of the resin reference member 64 are in contact with a flat surface 72a (reference surface of the mounting device) of the mounding device 72. The flat surface defined by the plurality of raised portions 64c of the resin reference member 64 serves as a reference surface of the lens driving device 54. The mounting device 72 may chuck the lens driving device 54 by sucking it under air suction or may chuck the lens driving device 54 by holding it with arms 72b of the mounting device 72. The arms 72b may be provided with spring mechanisms (not illustrated) to hold the lens driving device 54. The lens barrel 51 is attached at a minimum tilt with reference to the top surface of the lens driving device 54 by the height positioning jig 71, and the top surface side reference surface of the lens driving device 54 (i.e. the flat surface formed by the plurality of raised portions 64c) is in contact with the flat surface 72a of the mounting device 72. This minimizes the tilt of the lens barrel 51 with respect to the flat surface 72a of the mounting device 72.

The following describes a step of mounting the lens driving device 54 containing the optical section 52 onto the imaging block.

The mounting device 72 places the lens driving device 54 onto the mounting surface 22a (back surface) of the imaging block via an adhesive while chucking the lens driving device 54 containing the optical section 52. Bonding and fixing are done with the lens driving device 54 kept chucked by the mounting device 72. Note here that the lens driving device 54 is kept chucked by the mounting device 72 until the adhesive cures and the tilt (angle) and position (height position) of the lens driving device 54 are determined by the tilt (angle) and position (height position) of the mounting device 72. Therefore, if the lens driving device 54 and the imaging block are bonded and fixed to each other in a state where the tilt of the mounting surface 22a of the imaging block with respect to the flat surface 72a of the mounting device 72 is minimized, the tilt of the optical axes of the optical lenses 28 with respect to the imaging element 23 can be minimized. It should be noted that the imaging block is loaded on the pedestal 27 or the like and the mounting device 72 applies a pressing force in the direction of an arrow so as to press the lens driving device 54 against the imaging block.

Note here that if variations in the dimensions of components (imaging blocks) are sufficiently small, it is impossible to pick an imaging block of the typical dimensions in advance and adjust the angle of the mounting device 72 at which the lens driving device 54 is placed on the imaging block. Alternatively, if it is necessary to absorb the variations in the dimensions of components (imaging blocks), it is possible to adjust the angle of the mounting device 72 for each imaging block to be assembled.

### SUMMARY

A camera module manufacturing apparatus according to Aspect 1 of the present invention is a camera module manufacturing apparatus for manufacturing a camera module 100 including an optical lens 28, a fixing member (lens fixing member 29) accommodating and holding the optical lens 28, an actuator (actuator block 21) that enables the fixing member (lens fixing member 29) to be moved and drives the optical lens 28 to be displaced along an optical axis, and an imaging block on which the actuator (actuator block 21) is mounted via an adhesive 25, the imaging block including a substrate 22 and an imaging element 23 packaged on the substrate 22 to capture an image formed by light from the optical lens 28, the camera module manufacturing apparatus including: a supporting section (pedestal 27) that directly supports the imaging element 23 horizontally from a side opposite to an imaging surface, the supporting section supporting only the imaging element 23; and a mounting section (actuator block mounting head 32) that mounts and fixes the actuator (actuator block 21) onto the substrate 22 horizontally in an at least partially floating state so that a central axis 26 of the optical lens 28 is perpendicular to the imaging surface of the imaging element 23 supported by the supporting section (pedestal 27).

According to the foregoing configuration, the supporting section (pedestal 27) supports the imaging element 23 from the side opposite to the imaging surface. This prevents the imaging element 23 from being affected by warpage, if any, of the substrate 22. Further, the actuator (actuator block 21) is fixed to the substrate 22 in a non-contact state. This allows the optical lens 28 to be fixed perpendicularly to the imaging surface of the imaging element 23 without being affected by the warpage of the substrate 22. This also makes it possible to use a wide range of choice for materials (ceramic, resin) of which the substrate 22 is made.

This makes it possible, without using a special manufacturing apparatus that has conventionally been used, to provide a camera module manufacturing apparatus that makes it possible to easily solve a reduction in resolving power due to the tilt of the imaging element 23.

In a camera module manufacturing apparatus according to Aspect 2 of the present invention, the mounting section (actuator block mounting head 32) holds the actuator (actuator block 21) on the substrate 22 horizontally in an at least partially floating state by sucking an upper surface of the actuator (actuator block 21) under air suction.

The foregoing configuration makes it easier to release hold than does a method for hold with an adhesion member for example, and also makes it easier to achieve horizontally stable hold than does a method for double-sided hold.

In a camera module manufacturing apparatus according to Aspect 3 of the present invention, the mounting section (actuator block mounting head 32) is provided with an irradiating fiber (UV fiber 37) that radiates ultraviolet rays 42 toward the adhesive 25.

In a camera module manufacturing apparatus according to Aspect 4 of the present invention, the mounting section (actuator block mounting head 32) is provided with a heater that blows out hot air toward the adhesive 25.

The foregoing configuration allows the apparatus to be compact with an integrated structure.

In a camera module manufacturing apparatus according to Aspect 5 of the present invention, the mounting section (actuator block mounting head 32) includes a diffusion prevention section (cover 41) that prevents the ultraviolet rays 42 with which the adhesive 25 is irradiated from diffusing out of the camera module 100.

In a camera module manufacturing apparatus according to Aspect 6 of the present invention, the mounting section (actuator block mounting head 32) includes a diffusion prevention section (cover 41) that prevents the hot air to which the adhesive 25 is exposed from diffusing out of the camera module 100.

The foregoing configuration makes it possible to prevent exposure to the ultraviolet rays or the hot air of an adhesive of another camera module placed in the immediate vicinity during line work.

In a camera module manufacturing apparatus according to Aspect 7 of the present invention, the actuator includes a metal cover and a resin reference member on a subject's side thereof, at least a first portion of the resin reference member is more raised toward the subject's side than any other portion of the resin reference member and exposed from the metal cover, and positioning of the optical lens 28 with respect to the actuator (actuator block 21) is effected with reference to the first portion of the resin reference member.

According to the foregoing configuration, the positioning of the optical lens 28 is effected with reference to the first portion of the resin reference member that is raised toward the subject's side. This makes it possible to set consistent references for both assembly of the optical lens 28 and assembly by which the actuator (actuator block 21) is mounted onto the imaging block.

A camera module manufacturing method according to Aspect 8 of the present invention is a camera module manufacturing method for manufacturing a camera module 100 including an optical lens 28, a fixing member (lens fixing member 29) accommodating and holding the optical lens 28, an actuator (actuator block 21) that enables the fixing member (lens fixing member 29) to be moved and drives the optical lens 28 to be displaced along an optical axis, and an imaging block including a substrate 22 and an imaging element 23 packaged thereon to capture an image formed by light from the optical lens 28, the camera module manufacturing method including: a supporting step of directly supporting the imaging element 23 horizontally from a side opposite to an imaging surface, by use of a supporting section which supports only the imaging element 23; and a mounting step of mounting the actuator (actuator block 21) onto the imaging block via an adhesive 25, wherein, in the mounting step, the actuator (actuator block 21) is mounted and fixed onto the substrate 22 horizontally in an at least partially floating state so that a central axis 26 of the optical lens 28 is perpendicular to the imaging surface of the imaging element 23 supported in the supporting step.

This makes it possible, without using a special manufacturing apparatus that has conventionally been used, to provide a camera module manufacturing method that makes it possible to easily solve a reduction in resolving power due to the tilt of the imaging element 23.

In a camera module manufacturing method according to Aspect 9 of the present invention, the mounting step includes a holding step of holding the actuator (actuator block 21) in a horizontal position with respect to the substrate 22 by sucking an upper surface of the actuator (actuator block 21) under air suction.

The foregoing configuration makes it easier to achieve hold and release hold than do a method for hold with an adhesion member or a method for hold with a magnet obtained by magnetizing the actuator.

In a camera module manufacturing method according to Aspect 10 of the present invention, the mounting step includes a fixing step of fixing the actuator (actuator block 21) to the substrate 22 in a non-contact state.

According to the foregoing configuration, the actuator (actuator block 21) is fixed to the substrate 22 in a non-contact state. This allows the optical lens 28 to be fixed perpendicularly to the imaging surface of the imaging element 23 without being affected by the warpage of the substrate 22.

In a camera module manufacturing method according to Aspect 11 of the present invention, it is preferable that the adhesive 25 be an ultraviolet curable adhesive or a thermosetting adhesive.

In a camera module manufacturing method according to Aspect 12 of the present invention, in mounting the actuator (actuator block 21) onto the substrate 22 in the mounting step, the adhesive 25 is applied to such a degree as to be squeezed out from a space between the actuator (actuator block 21) and the substrate 22.

The foregoing configuration makes it possible to easily expose the resin to ultraviolet rays or hot air.

In a camera module manufacturing method according to Aspect 13 of the present invention, the optical lens is slidable with respect to the fixing member before being fixed in the fixing member, the camera module manufacturing method further including: a placing step of bringing a subject's side reference surface of the actuator into contact with a first reference surface of a height positioning jig; and an optical section fixing step of sliding the optical lens within the fixing member and fixing the optical lens in the fixing member in a position where the optical lens comes into contact with a second reference surface of the height positioning jig, wherein, in the mounting step, the actuator is mounted onto the imaging block via the adhesive after the height positioning jig has been detached.

According to the foregoing configuration, the positioning and fixing of the optical lens 28 with respect to the actuator are effected with reference to the reference surface of the actuator (actuator block 21) that faces the subject's side. This makes it possible to set consistent references for both assembly of the optical lens 28 and assembly by which the actuator (actuator block 21) is mounted onto the imaging block.

In a camera module manufacturing apparatus according to Aspect 14 of the present invention, the imaging element 23 is mounted on a mounting surface 22c of the substrate 22, and the actuator is provided on a back surface of the mounting surface 22c of the substrate 22.

In a camera module manufacturing method according to Aspect 15 of the present invention, the imaging element 23 is mounted on a mounting surface 22c of the substrate 22, and the actuator is provided on a back surface of the mounting surface 22c of the substrate 22.

The present invention is not limited to the description of the embodiments above, but may be altered within the scope of the claims. An embodiment based on a proper combination of technical means disclosed in different embodiments is encompassed in the technical scope of the present invention. Furthermore, a new technical feature may be formed by combining technical means disclosed in each separate embodiment.

### INDUSTRIAL APPLICABILITY

The present invention relates to methods and apparatuses for manufacturing camera modules that are incorporated into mobile devices such as mobile information terminals and mobile phones and, in particular, to a camera module manufacturing method and a camera module manufacturing apparatus by which a lens fixing member including an optical lens, an actuator block that enables the lens fixing member to be moved, and an imaging element are positioned parallel to one another and fixed.

### REFERENCE SIGNS LIST

21 Actuator block (actuator)

22, 22A Substrate

22d Through-hole

23 Imaging element

24, 24A Stage

24a Pin

25 Adhesive

25a Squeezed-out adhesive

26 Central axis

27 Pedestal

27a Flat surface

28 Optical lens

29 Lens fixing member (fixing member)

32 Actuator block mounting head (mounting section)

33 UV irradiator

34 Ultraviolet rays

37 UV fiber

39 UV fiber fixing member

41 Cover

42 Ultraviolet rays

64 Resin reference member

71 Height positioning jig

100, 100A Camera module

1. A camera module manufacturing apparatus for manufacturing a camera module including an optical lens, a fixing member accommodating and holding the optical lens, an actuator that enables the fixing member to be moved and drives the optical lens to be displaced along an optical axis, and an imaging block on which the actuator is mounted via an adhesive, the imaging block including a substrate and an imaging element packaged on the substrate to capture an image formed by light from the optical lens, the camera module manufacturing apparatus comprising:
a supporting section that directly supports the imaging element horizontally from a side opposite to an imaging surface, the supporting section supporting only the imaging element; and
a mounting section that mounts and fixes the actuator onto the substrate horizontally in an at least partially floating state so that a central axis of the optical lens is perpendicular to the imaging surface of the imaging element supported by the supporting section.

2. The camera module manufacturing apparatus according to claim 1, wherein the actuator includes a metal cover and a resin reference member on a subject's side thereof,
at least a first portion of the resin reference member is more raised toward the subject's side than any other portion of the resin reference member and exposed from the metal cover, and
positioning of the optical lens with respect to the actuator is effected with reference to the first portion of the resin reference member.

3. A camera module manufacturing method for manufacturing a camera module including an optical lens, a fixing member accommodating and holding the optical lens, an actuator that enables the fixing member to be moved and drives the optical lens to be displaced along an optical axis, and an imaging block including a substrate and an imaging element packaged thereon to capture an image formed by light from the optical lens, the camera module manufacturing method comprising:
a supporting step of directly supporting the imaging element horizontally from a side opposite to an imaging surface, by use of a supporting section which supports only the imaging element; and
a mounting step of mounting the actuator onto the imaging block via an adhesive,
wherein, in the mounting step, the actuator is mounted and fixed onto the substrate horizontally in an at least partially floating state so that a central axis of the optical lens is perpendicular to the imaging surface of the imaging element supported in the supporting step.

4. The camera module manufacturing method according to claim 3, wherein the mounting step includes a fixing step of fixing the actuator to the substrate in a non-contact state.

5. The camera module manufacturing method according to claim 3, wherein in mounting the actuator onto the substrate in the mounting step, the adhesive is applied to such a degree as to be squeezed out from a space between the actuator and the substrate.

6. The camera module manufacturing method according to claim 3, wherein the optical lens is slidable with respect to the fixing member before being fixed in the fixing member, the camera module manufacturing method further comprising:
a placing step of bringing a subject's side reference surface of the actuator into contact with a first reference surface of a height positioning jig; and
an optical section fixing step of sliding the optical lens within the fixing member and fixing the optical lens in the fixing member in a position where the optical lens comes into contact with a second reference surface of the height positioning jig,
wherein, in the mounting step, the actuator is mounted onto the imaging block via the adhesive after the height positioning jig has been detached.

7. The camera module manufacturing apparatus according to claim 1, wherein the imaging element is mounted on a mounting surface of the substrate, and the actuator is provided on a back surface of the mounting surface of the substrate.

8. The camera module manufacturing method according to claim 3, wherein the imaging element is mounted on a mounting surface of the substrate, and the actuator is provided on a back surface of the mounting surface of the substrate.
